(19) United States
(12) Patent Application Publication
(10) Pub. No.: US 2025/0107033 A1
(43) Pub. Date: Mar. 27, 2025

(54) Apparatus and Method for Dissipating Heat from Electronics

(71) Applicant: Infinera Corporation, San Jose, CA (US)

(72) Inventors: Anand Jittanakatti, Bangaluru (IN); Jatin Kohli, Bangaluru (IN); Sundaresan Kumarasamy, Puducherry (IN)

(21) Appl. No.: 18/898,373

(22) Filed: Sep. 26, 2024

Related U.S. Application Data
(60) Provisional application No. 63/540,585, filed on Sep. 26, 2023.

(51) Int. Cl. H05K 7/20

(52) U.S. Cl. CPC H05K 7/20145; H05K 7/20154; H05K 7/20727

(57) ABSTRACT

Embodiments are provided for the design of a drafted air duct employed in a networking chassis to achieve sufficient airflow for electronics, such as optical transceiver pluggable modules, for efficient and effective cooling. Some embodiments help in forcing the airflow through an integrated heatsink of the electronics to improve its and networking equipment's thermal performance by providing an efficient cooling solution. Computational fluid dynamics (CFD) simulations may be used to custom design the performance of various air duct profiles and optimization of air duct design parameters, such as duct geometry, intake aperture cross-sectional area, and exhaust aperture cross-sectional area, to maximize cooling rate.

### RELATED APPLICATION(S)

This application claims the benefit of U.S. Provisional Application No. 63/540,585, filed on Sep. 26, 2023. The entire teachings of the above application(s) are incorporated herein by reference.

### BACKGROUND

Optical transceivers play a critical role in modern telecommunications and serve as a conduit between optical and electrical signals. Data transfer rates (hundreds of Gb/s) and power consumption (dozens of watts) in small form factors are expected to increase further with future enhancements in optical modules

The thermal design and cooling of such high-power optics poses a huge challenge. Conventional methods of cooling the optical transceiver modules have limitations and may not fully meet the operating temperature requirements of the optics in networking equipment. As such, there exists a need for new methods and cooling strategies that can maintain regulate temperature in higher speed and power modules to maintain the reliability and lifespan thereof.

### SUMMARY

Methods, apparatuses, and means are provided for dissipating heat from electronics through the configuring of a drafted air duct that fluidically couples an airflow of a system with internal convection cooling to influence an airflow in a passageway external thereof that contains at least a portion of the electronics and any heatsink thermally coupled thereto. Furthermore, the fluidically coupling of airflow induced by active convection cooling through a drafted air duct enhances the velocity of airflow in the airflow passageway contained within, enhancing heat dissipation over conventional approaches of passive convection cooling or uniform air ducts and potentially prolonging the reliability and lifespan of electronics positioned therein.

In example methods, apparatuses, and means, a drafted air duct is configured to enable air to flow through an airflow passageway from an intake port end and an exhaust port end, a cross-sectional area of an aperture defined by the intake port end being smaller than a cross-sectional area of an aperture defined by the exhaust port end. In addition, the exhaust port end is retained in a position that is in sufficient spatial proximity to a faceplate of a chassis that is permeable to a flow of air such that an airflow inside the chassis of a system with internal convection cooling can affect (i.e., be fluidically coupled to) an airflow within the airflow passageway of the drafted air duct.

The flat faceplate or a faceplate may be at least in part angled with respect to another part of the faceplate or chassis. The apparatus used to define the airduct may be formed of a single continuous material or composed from multiple flat or curved panels coupled together. Optionally, one or more of the panels may be tapered.

The apparatus may be configured to define a drafted air duct around at least a portion of one or more electronic components, e.g., optical transceivers, and to be assembled onto the faceplate of the chassis of the system with internal convection cooling or onto the electronics. The apparatus may also be configured to be an integrated component of the electronics or the chassis. Optionally, the drafted air duct may be defined by the fins of a heatsink thermally coupled to the electronics.

A method of dissipating heat from electronics may further include causing the active convectional cooling to commence within a chassis. An additional method may include enabling additional airflow to enter the airflow passageway through apertures, e.g., perforations, located adjacent to the intake port end.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

The foregoing will be apparent from the following more particular description of example embodiments, as illustrated in the accompanying drawings in which like reference characters refer to the same parts throughout the different views. The drawings are not necessarily to scale, emphasis instead being placed upon illustrating embodiments.

FIG. 1 is a schematic diagram of an example application of a drafted air duct as part of a computing server rack that connects to a network.

FIG. 2 is a schematic diagram that illustrates example optical transceiver modules.

FIGS. 3A-1 and -2 are schematic diagrams of an example apparatus configured to couple onto an optical transceiver module with an integrated heatsink (IHS) to define a drafted air duct.

FIG. 3B is a cross-sectional schematic of a drafted air duct and optical transceiver module of FIG. 3A integrated into the chassis of a system with internal convection cooling.

FIGS. 4A-1, -2, and -3 are diagrams comparing airflow through a uniform, narrow, and drafted air duct, respectively, coupled with a chassis plenum with a fan.

FIGS. 4B-1, -2, and -3 are diagrams comparing airflow through a uniform, narrow, and drafted air duct, respectively, of FIG. 3A with respect to an example electronic component.

FIGS. 5A-1a,b, -2a,b, and -3a,b are heatmap diagrams that illustrate results from computational fluid dynamics simulations of temperature, airflow velocity, and airflow velocity vectors, respectively, of an environment around an electronic component coupled to a chassis of a system with internal convection cooling operating at full fan speed with and without a drafted air duct.

FIGS. 5B-1a,b, -2a,b, and -3a,b are heatmap diagrams that illustrate results from computational fluid dynamics simulations of temperature, airflow velocity, and airflow velocity vectors, respectively, of an environment around an electronic component coupled to a chassis of a system with internal convection cooling operating at reduced fan speed with and without a drafted air duct.

FIGS. 6A-1 and -2 are diagrams that illustrate another example apparatus, with perforations adjacent to one end, that is configured to couple with a flat faceplate and tapered along a single panel.

FIGS. 6B-1 and -2 are diagrams that illustrate another example apparatus, with perforations adjacent to one end, that is configured to couple with a flat faceplate and tapered along all panels.

FIG. 6C-1 and -2 are schematic diagrams of the apparatuses of FIG. 6A-1 and -2 and FIG. 6B-1 and -2 configured to couple with one or more optical transceivers and the flat faceplate of a chassis of a system.

FIG. 6D is a cross-sectional diagram of a module in FIG. 6C-2, including the apparatus, optical transceiver module, and chassis.

FIGS. 7A-1 and -2 are diagrams that illustrate another example apparatus, with perforations adjacent to one end, that is configured to couple with an inclined faceplate and tapered along a single panel.

FIGS. 7B-1 and -2 are diagrams that illustrate another example apparatus, with perforations adjacent to one end, that is configured to couple with an inclined faceplate and tapered along all panels.

FIGS. 7C-1 and -2 are schematic diagrams of the apparatuses of FIG. 7A-1 and -2 and FIG. 7B-1 and -2 configured to couple with one or more optical transceivers and the inclined faceplate of a chassis of a system.

FIG. 7D is a cross-sectional diagram of a module in FIG. 7C-2, including the apparatus, optical transceiver module, and chassis.

FIGS. 8A-1, -2, and -3 are diagrams that illustrate another example apparatus, with perforations adjacent to one end, that is configured to couple with a flat faceplate of a chassis and curved along one panel.

FIGS. 8B-1, -2, and -3 are diagrams that illustrate another example apparatus, with perforations adjacent to one end, that is configured to couple with a flat faceplate of a chassis and curved along all panels.

FIG. 9A is an exploded diagram of several inter-connected apparatuses configured to couple onto the faceplate of chassis through the use of fasteners.

FIG. 9B is a schematic diagram of the interconnected apparatuses of FIG. 9A coupled onto the faceplate of chassis through the use of fasteners.

FIG. 10A is a diagram that illustrates an alternative embodiment in which a drafted air duct is formed by fins of a heatsink thermally coupled to an optical transceiver module.

FIG. 10B is a diagram that illustrates the embodiment of FIG. 10A coupled with the chassis of a system.

FIG. 10C illustrates a cross-sectional diagram of an interconnection of the embodiment of FIG. 10A with a chassis as shown in FIG. 10B.

### DETAILED DESCRIPTION

A description of example embodiments follows.

Methods and apparatuses for dissipating heat from electronics by leveraging the internal airflow of a system with active convection cooling are described herein.

Heat generation is an intrinsic characteristic of electronics. Moreover, electronic components perform optimally within specific temperature ranges and can be damaged by significant deviations therefrom. As such, thermal regulation plays an important role in maintaining the reliability and lifespan of electronics.

Fiber-optic communication is an example application in which there is a growing need for effective thermal regulation. Fiber-optic communication utilizes pulses of light to transmit information from one location to another. The strengths of fiber-optics, including high bandwidth, high fidelity over long distances, and immunity to electromagnetic interference has led to increasing adoption in both local and long-distance communications. Moreover, modern computing applications, including cloud computing, data centers, and artificial intelligence, impose significant demands upon data transfer speeds.

Optical transceiver modules, e.g., quad small form-factor pluggable (QSFP)-28 and quad small form-factor pluggable double density (QSFP-DD) modules, convert optical signals into electronic signals and vice versa. To meet modern data transfer needs, optical transceiver modules with greater capacities for data transfer rates, e.g., 100 Gb/s, 400 Gb/s, and 800 Gb/s, and with smaller and more compact form factors, are being developed. For example, QSFP-28 optical modules have a data transfer rate of 100 Gb/s and power consumption of approximately 4.5 W. Currently, QSFP-DD LR4/ZR/ZR+/XR optical modules, which are of similar size and form factor, are able to transfer data at rates of 400 Gb/s to 800 GB/s over longer/higher ranges, but with increased power consumption of approximately 14 W to 28 W (3× to 6× that of QSFP-28 modules), resulting in significantly greater heat generation. Thermal design and cooling of such high-power optics would be a huge challenge and conventional methods of cooling the optics have limitations and cannot meet the operating requirements of the optics in the networking equipment. Finding new methods and cooling strategies are important towards maintaining the reliability and life of these components.

Optical transceiver modules are typically configured to interface with a system, e.g., a network switch, including two sections: a body or digital signal processor (DSP) portion that is positioned within a chassis of the system and a nose or transmit-receive optical sub-assembly (TROSA/TOSA) protruding outside of the chassis.

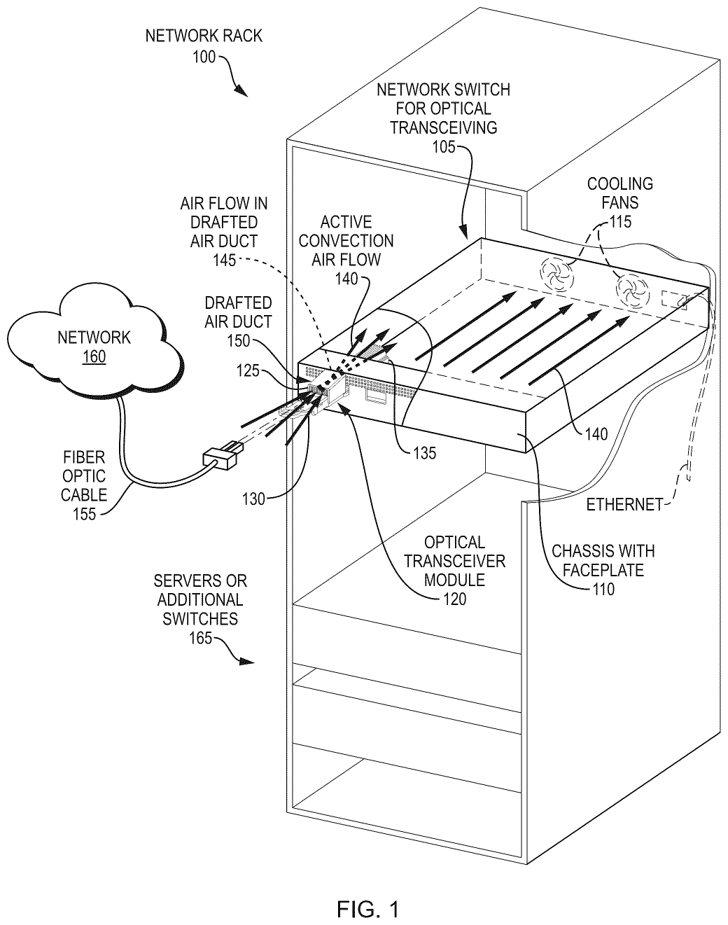

FIG. 1 illustrates an example network server rack 100 including a network switch 105 and potential additional network switches and servers 165. The network switch 105 includes a chassis 110 and an active cooling system, e.g., fans 115. The network switch 105 can also be configured to couple with at least one optical transceiver module 120, e.g., a QSFP028 or a QSFP-DD module. The example optical transceiver module 120 includes a body section 135 positioned within the chassis 110 of the network switch 105 and a nose section 130 positioned external to the chassis 110. The optical transceiver module 120 connects to a network 160 through a fiber optic cable 155.

The fans 115 of the network switch 105 generate an airflow 140 that provides active convection cooling within the chassis 110, including for the body 135 of an optical transceiver 120. The airflow 140 is less effective in cooling the nose 130 of the optical transceiver 120 positioned external to the chassis 110.

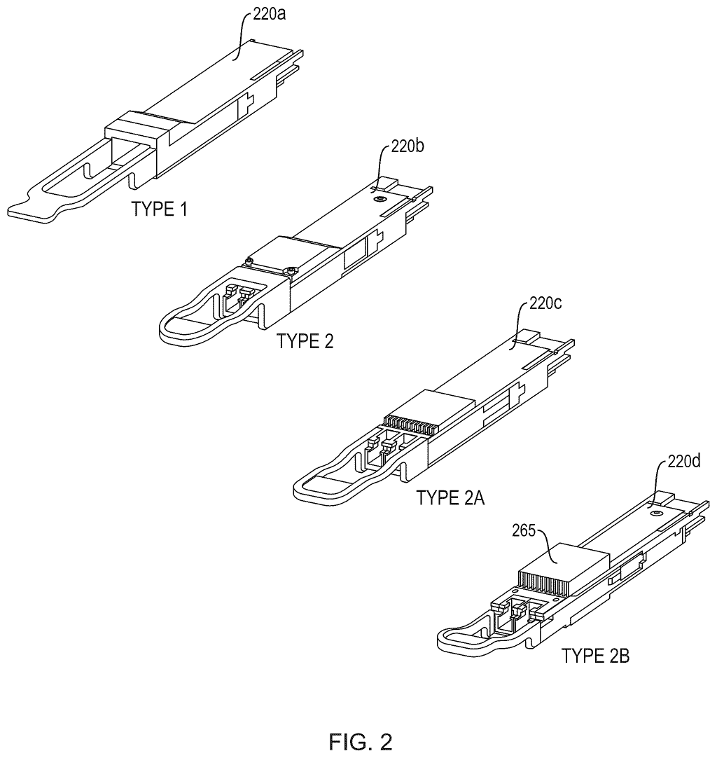

FIG. 2 illustrates example optical transceiver modules with which example embodiments described herein or otherwise contemplated may be applied. The QSFP-DD Type 1 220a is consistent with the mechanical characteristics of the QSFP-28 and the Type 2 220b have a longer extension beyond the faceplate that module manufacturers can take advantage of for extra design room internal to the module. Type 2A 220c is a further variant on Type 2 220b and has an integrated heatsink (IHS) on the nose of the module to facilitate cooling with an efficient secondary heat transfer path. Type 2B increases the height of the nose heatsink 265 to take advantage of the increased connector port separation defined for QSFP-DD 800. All module variants in this example embodiment are compatible with the common QSFP-DD connector and cage designs and can be mixed in a deployment.

Even though Type 2A 220c and Type 2B 220d QSFP-DD modules have extra design room internal to the module and cooling of the nose section with IHS, they have their own challenges in thermal regulation due to higher power dissipation and the IHS being located outside of the chassis 110 in an open space. Further, the QSFP-DD modules are off-the-shelf parts and cannot be easily modified. As such, the airflow in/of the system 105 with a chassis 110 is not that effective in cooling them, making it difficult to meet the temperature requirements of the QSFD-DD modules and the industry standard requirements of the Network Equipment-Building System (NEBS) and European Telecommunications Standards Institute (ETSI) compliance for the system and chassis.

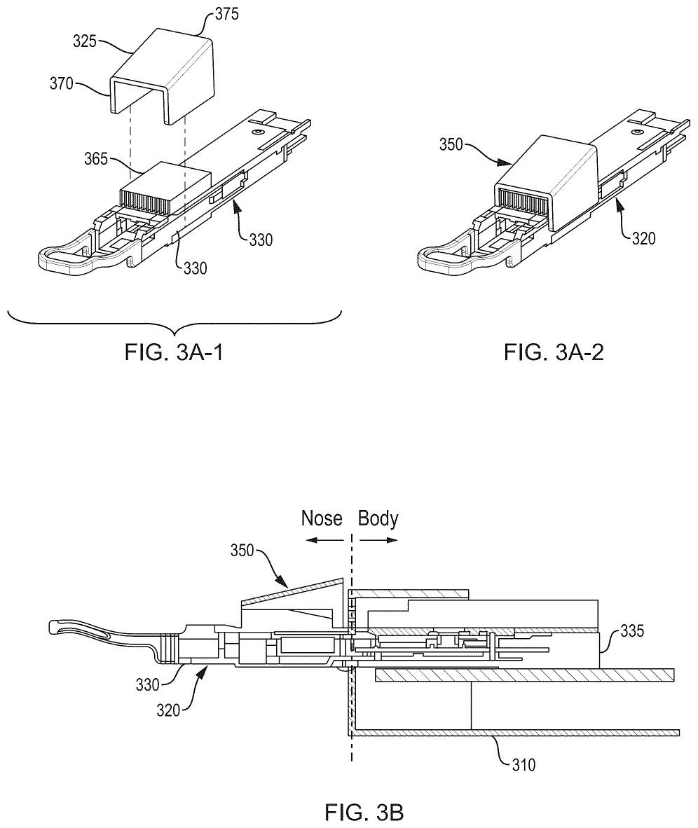

FIGS. 3A-1 and -2 and FIG. 3B illustrate an example apparatus 325 (125 in FIG. 1) for dissipating heat from electronics on a nose 330 of an optical module 320 with a body 335 position within a chassis 310 of a system. The apparatus includes an intake port end 370 and an exhaust port end 375 defining at least a portion of a boundary of an intake and exhaust aperture, respectively, and a drafted air duct 350 (150 in FIG. 1) spanning between the intake port end and exhaust port end that defines an airflow passageway, allowing airflow through the duct (145 in FIG. 1), with sufficient volume to contain the electronics and any heatsinks 365 thermally coupled thereto. The area of the aperture of the intake port end 370 is smaller than the area of the aperture of the exhaust port end 375.

FIG. 3B provides a cross-sectional view of the drafted air duct 350, optical transceiver 320, and faceplate of the chassis 310 of FIG. 3A. The exhaust port end of the drafted air duct 350 is positioned in sufficient spatial proximity to the chassis 310 to fluidically couple the airflow in the internal space of the chassis, for example airflow from active convection cooling using a fan, with the airflow passageway.

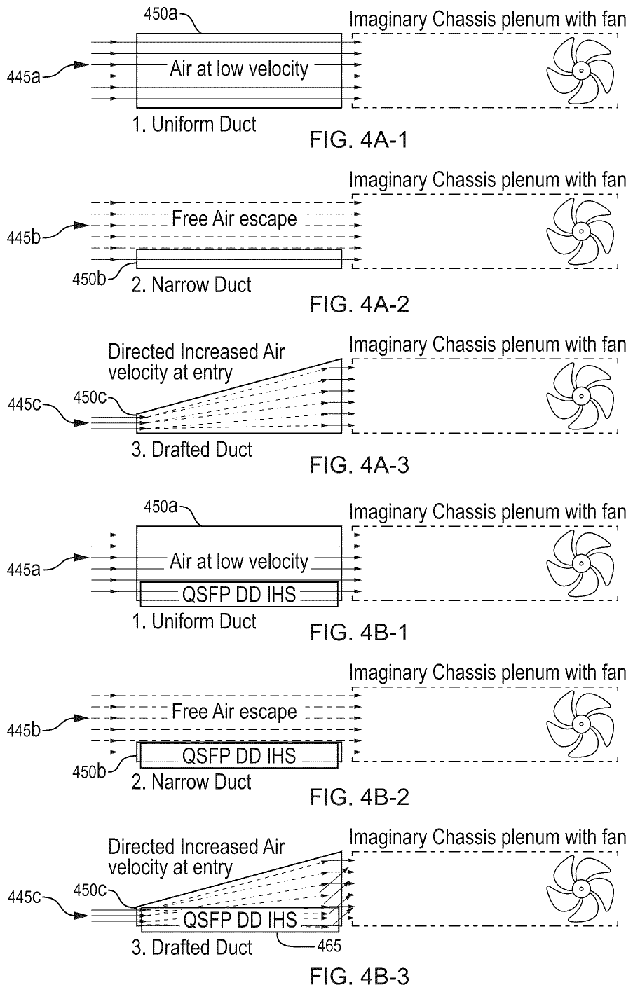

FIGS. 4A and 4B illustrate diagrammatically the influence of air ducts fluidically coupled with a chassis with internal connection cooling, e.g., a fan, upon the airflow within the airflow passageways defined by the ducts. As shown in FIG. 3B, the drafted air duct 350 has varying cross-sectional area from one end to the other. From the law of continuity of flow, in the drafted air duct, airflow velocity will be higher at locations with smaller cross-sectional area and will be lower at locations with larger cross-sectional area. The drafted air duct is an aggregate collector at the larger exhaust port end and converges airflow in the smaller intake port end, helping focus the air jet (high velocity air) at a particular point of a concentrated zone.

FIGS. 4A-1 and 4A-2 illustrate that airflow 445a through a uniform duct 450a (FIG. 4A-1), e.g., having a uniform cross-sectional area between the intake to exhaust port ends, flows at a low and constant velocity, and in a narrow duct 450b (FIG. 4A-2), free airflow 445b is not effectively captured and guided through the duct. For a drafted air duct 450c (FIG. 4A-3), however, the airflow 445c from the chassis with active convection cooling is collected and concentrated at the intake port end. This concentrated high velocity airflow at the intake port end helps in effective heat extraction.

FIGS. 4B-1, 4B-2, and 4B-3 illustrate the same airflow patterns of FIGS. 4A-1, 4A-2, and 4A-3, respectively, but with respect to an integrated heatsink 465 of an example optical transceiver module positioned within the airflow passageways defined by the uniform, narrow, and drafted air ducts.

To validate the concept, computational fluid dynamics (CFD) simulations have been performed comparing the temperature, airflow velocity, and airflow velocity vectors of a QSFP-DD Type 2 optical module plugged into a chassis with and without a drafted air duct. For these simulations, chassis geometry, perforations on the faceplate that allow airflow through the chassis, and fan speeds are kept constant for simulations with and without the drafted air duct. Additionally, two sets of experiments, including a high fan speed simulation with 45 degree Celsius ambient temperature and a low fan speed simulation with 28 degrees Celsius ambient temperature, are performed. The low fan speed setting is 30% of the maximum (high) fan speed.

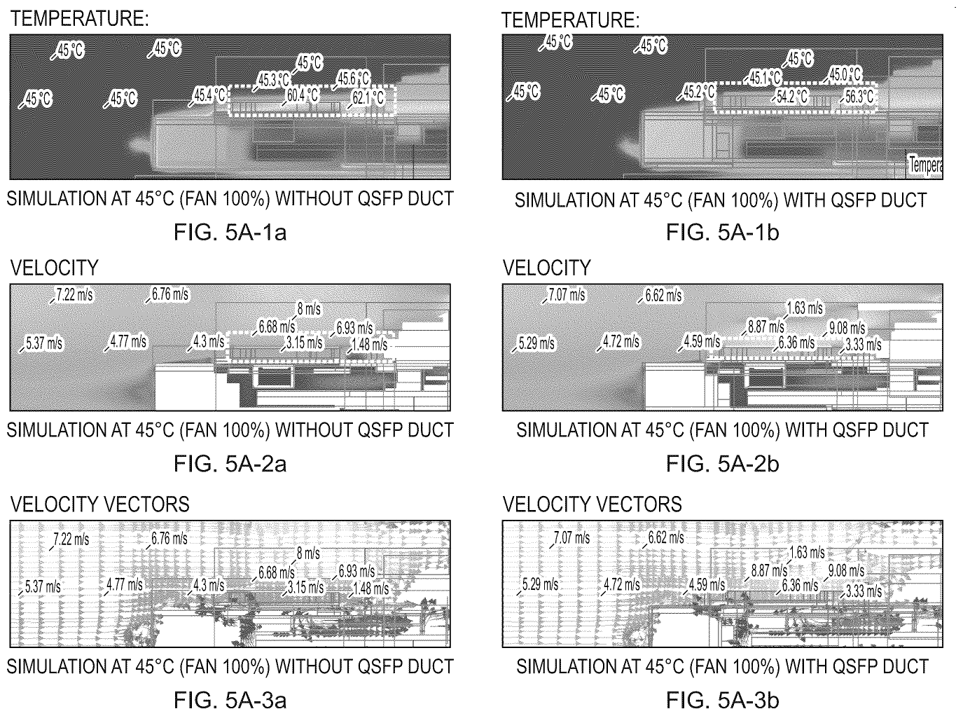

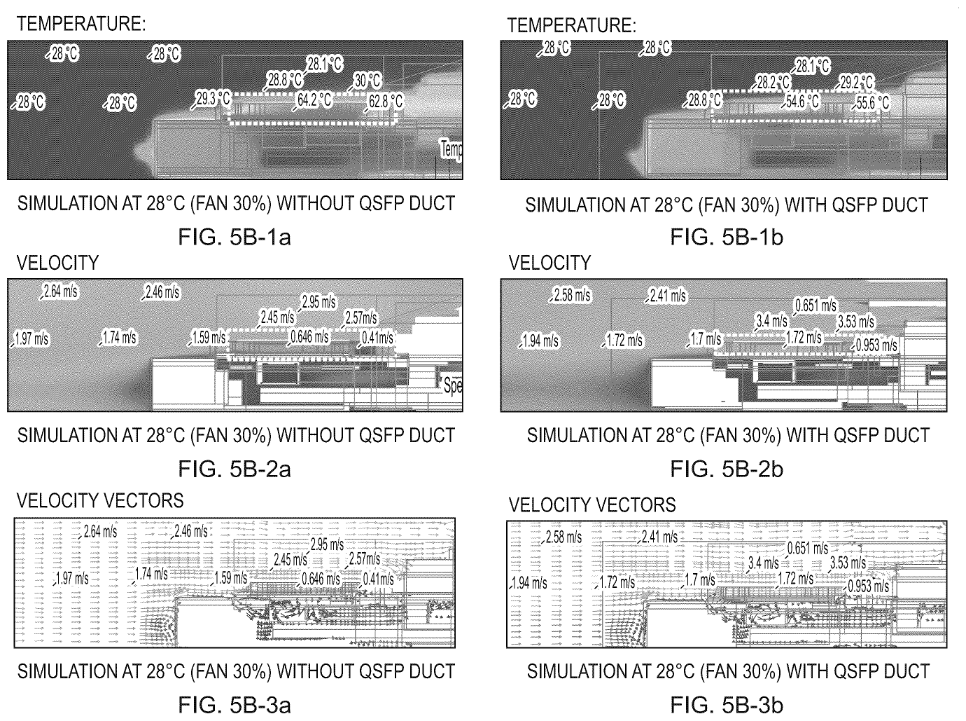

FIGS. 5A-1a,b, -2a,b and -3a,b and 5B-1a,b, -2a,b, and -3a,b report CFD simulation results of temperature, velocity, and velocity vector, respectively. Regions enclosed within the dashed lines represent a volume within a drafted air duct, if present. Simulation results indicate temperature reductions of 5 to 10 degree Celsius and approximately two-fold increases in airflow velocity in these regions when a drafted air duct is present. Furthermore, temperature monitors internal to the optical transceiver module indicate temperature reductions of approximately 4 to 6 degree Celsius at critical to function areas.

The drafted duct design can be introduced in multiple ways. Example embodiments are provided below and can be applied in all applications using QSFP-DD modules, including the Type 1, 2, 2A & 2B shown in FIG. 2, as well as other future optical transceiver modules with integrated heatsinks.

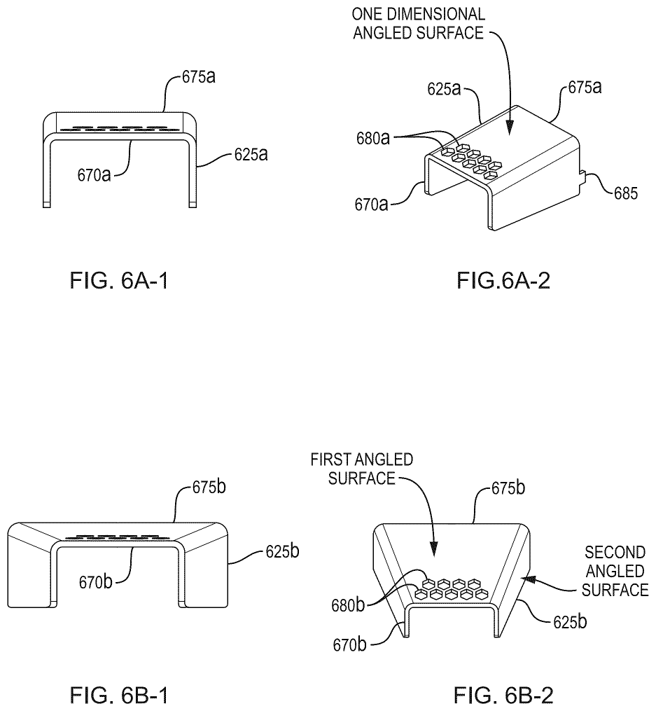

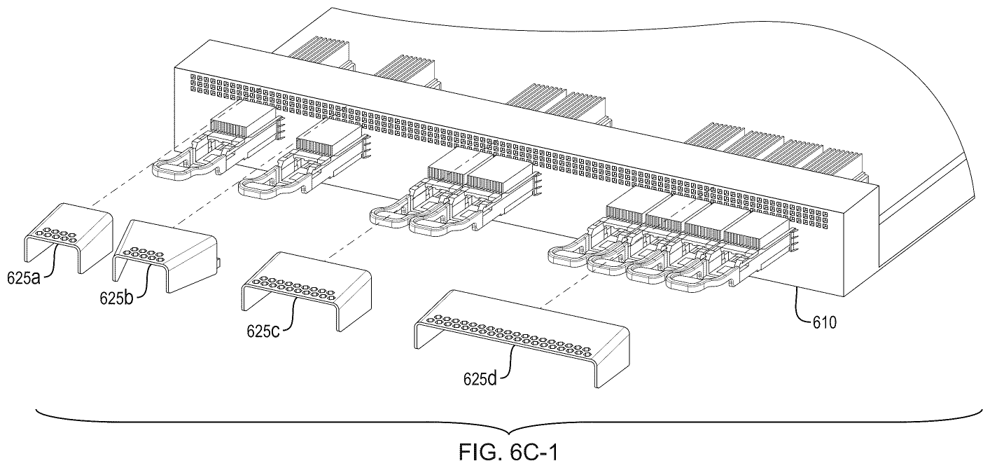

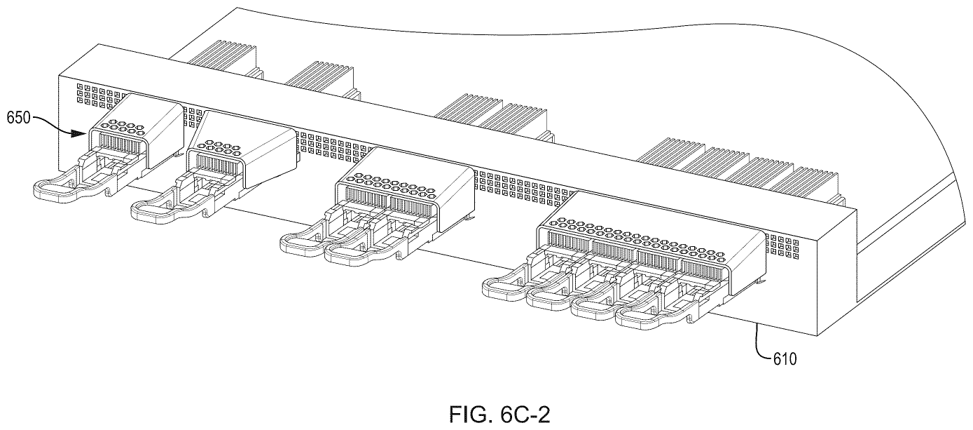

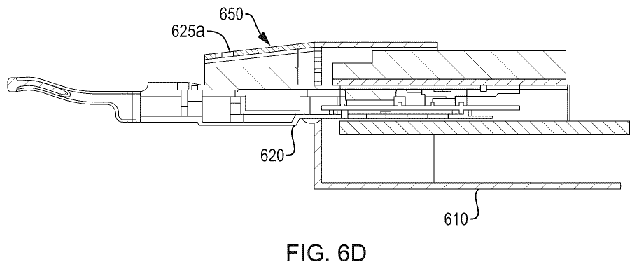

FIGS. 6A-6D in general illustrate example embodiments of apparatuses configured to couple with a chassis of a system with a flat faceplate. FIGS. 6A-1 and -2 are schematics of an example apparatus 625a, with an intake port end 670a and exhaust port end 675a, that can include three panels, including one angled panel, and optional vent openings 680a (perforations) adjacent to the intake port end 670a. The apparatus can further include a notch 685 to improve coupling with a faceplate of a chassis (610 in FIGS. 6C-1 and -2). FIGS. 6B-1 and -2 are schematics of another example apparatus 625b, likewise with intake port end 670b and exhaust port end 675b, comprising three panels, including multiple panels are angled, and optional vent openings 680b adjacent to the intake port end 670b.

FIGS. 6C-1 and -2 provide exploded and isometric schematics, respectively, of drafted air ducts configured using the apparatuses of FIGS. 6A-1 and -2 and 6B-1 and -2 with a chassis 610 with a flat faceplate. Additional embodiments include drafted air ducts around an individual or a plurality of optical transceiver modules, including 1×1, 1×2 625c, and 1×4 625d configurations. FIG. 6D provides a cross-sectional view of the drafted air duct 650, optical transceiver module 620, and chassis 610 for the 1×1 apparatus 625a angled along one panel.

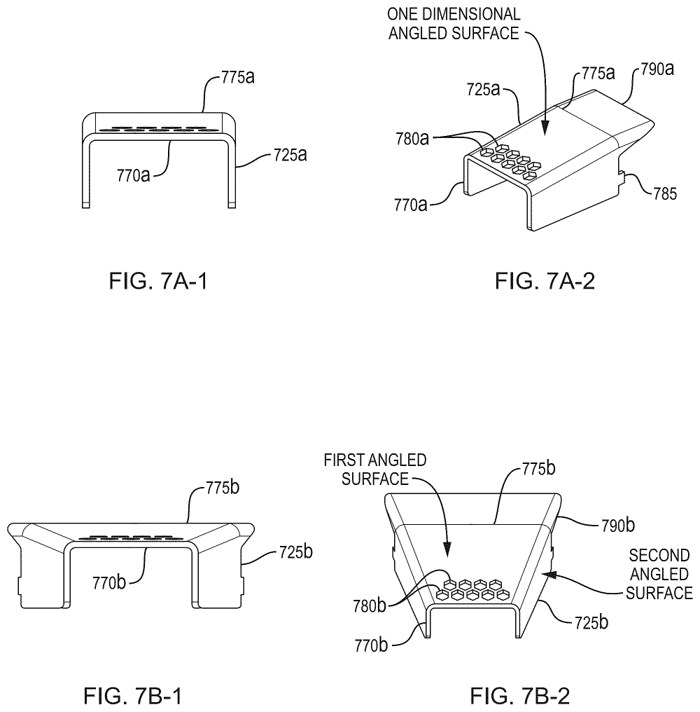

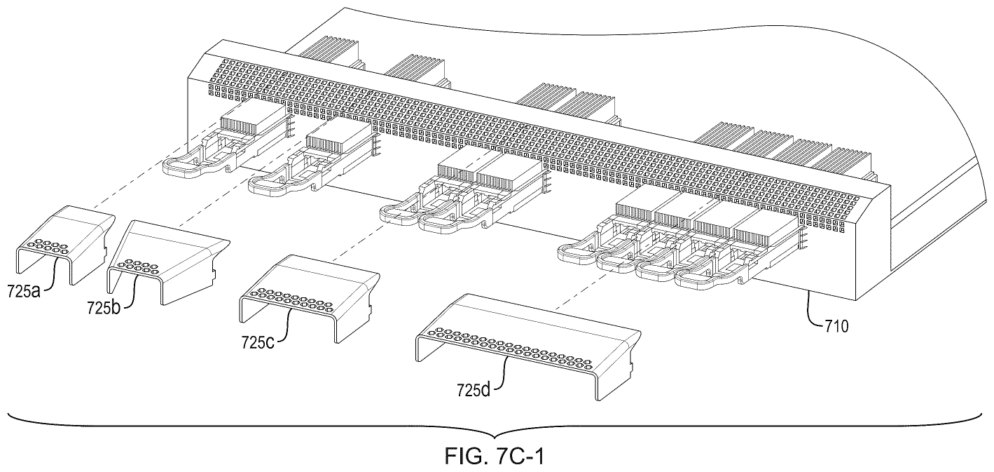

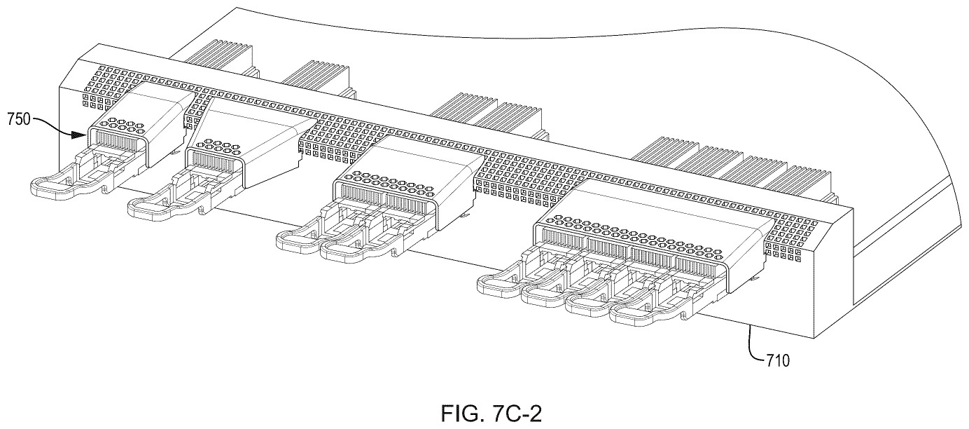

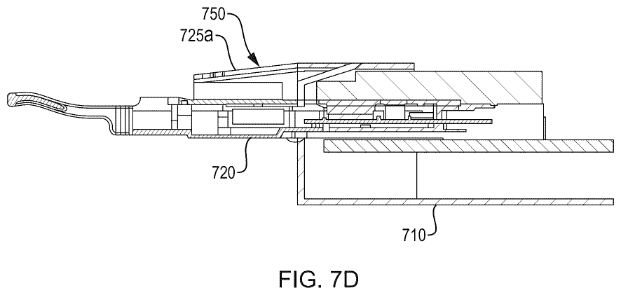

As with FIGS. 6A-6D, FIGS. 7A-7D in general illustrate additional example embodiments of an apparatus configured to couple with a chassis of a system with an inclined faceplate. FIGS. 7A-1 and -2 are schematics of an example apparatus 725a, with an intake port end 770a and exhaust port end 775a, that can include three panels, including one angled panel, and optional vent openings 780a (perforations) adjacent to the intake port end 770a. The apparatus can further include a notch 785 to improve coupling with a faceplate of a chassis (710 in FIGS. 7C-1 and -2). FIGS. 7B-1 and -2 are schematics of another example apparatus 725b, likewise with intake port end 770b and exhaust port end 775b, comprising three panels, including multiple panels are angled, and optional vent openings 780b adjacent to the intake port end 770b. The apparatuses are further configured to extend 790A (and 790B) and maintain fluidic coupling along the inclined surface of a faceplate, as illustrated in FIGS. 7C-1 and -2.

FIGS. 7C-1 and -2 provide exploded and isometric schematics, respectively, of drafted air ducts configured using the apparatuses of FIGS. 6A-1 and -2 and 6B-1 and -2 with a chassis 710 with an inclined faceplate. Additional embodiments include drafted air ducts around an individual or a plurality of optical transceiver modules, including 1×1, 1×2 725c, and 1×4 725d configurations. FIG. 7D provides a cross-sectional view of the drafted air duct 750, optical transceiver module 720, and chassis 710 for a 1×1 apparatus 725a angled along one panel.

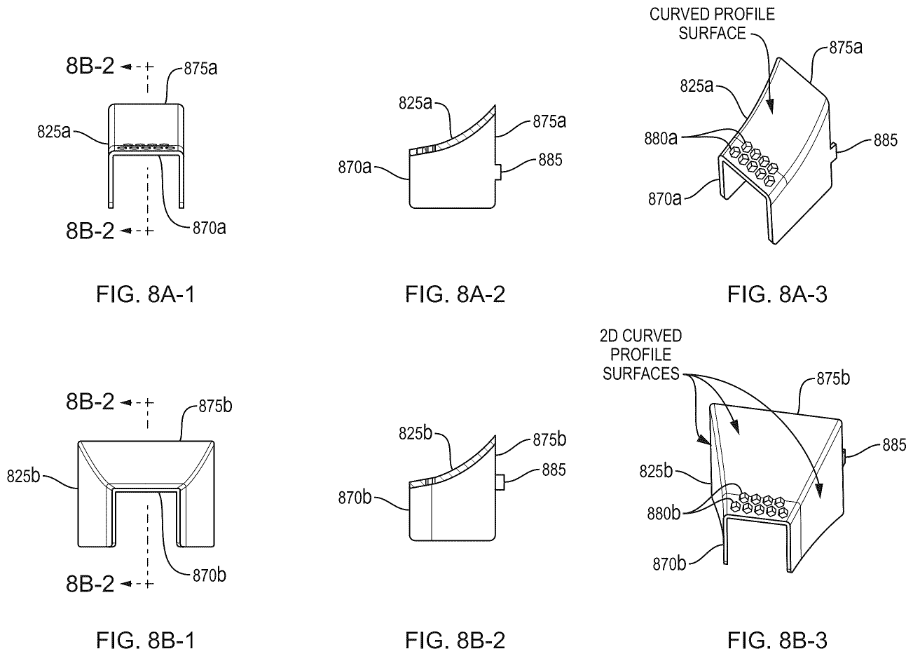

As with FIGS. 6A-6B, FIGS. 8A-8B illustrate another example embodiment in which one or more of the panels of the apparatus are curved. The curved profile can be implemented in one or more of the panels comprising the apparatus. FIGS. 8A-1, -2, and -3 illustrate an example apparatus 825a, with intake port end 870a and exhaust port end 875a, that can include three panels, including one curved panel. The apparatus 825a can also include optional vent openings 880a and a notch 885 to improve coupling with a faceplate of a chassis. FIGS. 8B-1, -2, and -3 illustrate another example apparatus 825b, with intake port end 870b and exhaust port end 875b, comprising three panels, including multiple curved panels, and optional vent openings 880b adjacent to the intake port end 870a.

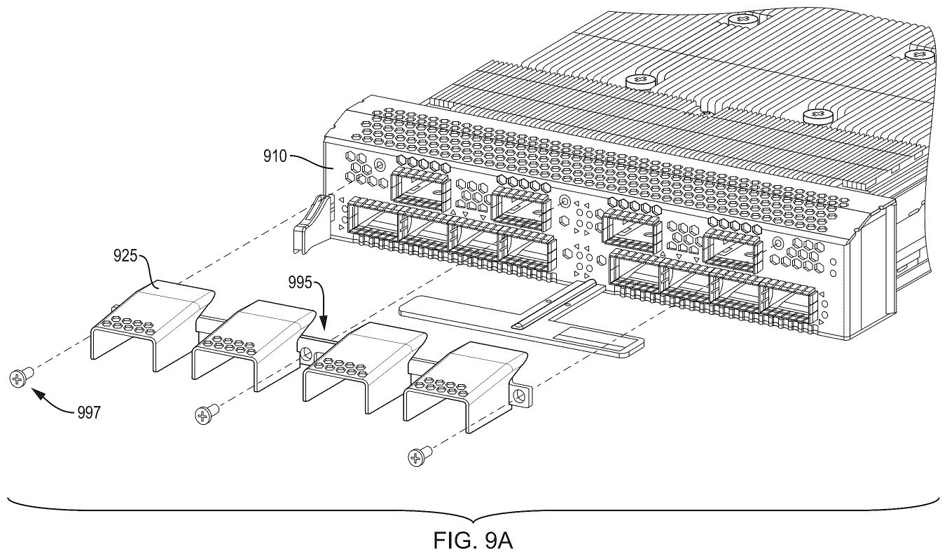

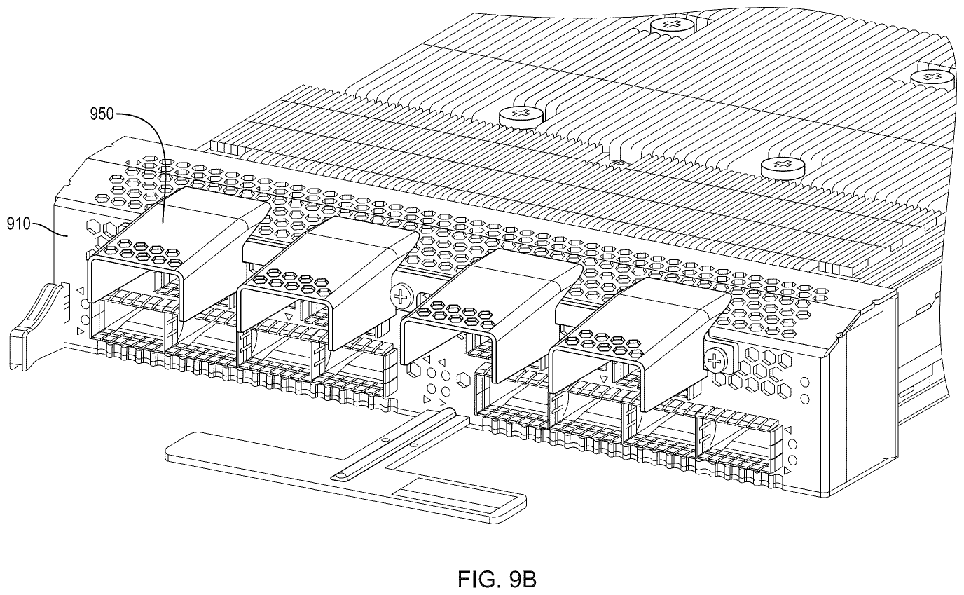

FIGS. 9A-9B are schematics of another example embodiment of an apparatus 925 configured to couple with a chassis with an inclined faceplate 910. A plurality of drafted air ducts 950 can be configured to each define an airflow passageway around an individual of a plurality of optical transceivers. Further, the plurality of drafted air ducts can be interconnected 995 with respect to one another and configured to assemble onto the chassis 910 using a fastener 997, such as a screw, clamp, hook and loop fabric, or other fastener component(s) known in the art.

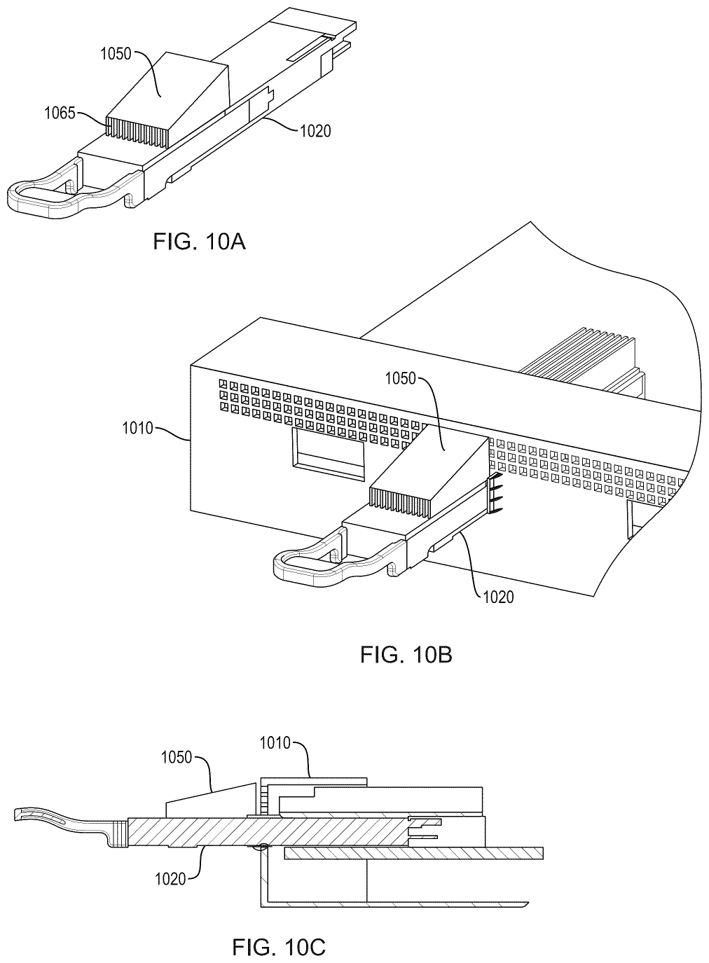

As illustrated in FIG. 10A, in a further embodiment, a drafted air duct 1050 may be configured by the fins of an integrated heat sink 1065 thermally coupled to an optical transceiver module 1020. FIG. 10B is an isometric schematic of the drafted air duct 1050 fluidically coupled with a flat faceplate of a chassis 1010 and FIG. 10C illustrates a cross-sectional view of the drafted air duct 1050, optical transceiver module 1020, and face plate 1010.

In some embodiments, the apparatus can be formed of a single continuous material and molded to form the drafted air duct. In additional embodiments, the apparatuses can comprise a plurality of panels coupled together, as illustrated in FIGS. 6A-D, 7A-D, and 8A-B. This coupling can include welding, gluing, and fastening or other coupling technique known in the art. The apparatuses can further be tapered along one or a plurality of panels.

In further embodiments, the apparatus may comprise an exhaust port end that defines an exhaust aperture of the same shape and of greater respective dimensions than the intake aperture defined by the intake port end. The shapes of the intake aperture and exhaust aperture may alternatively be different.

The apparatus may be an integrated component of the electronics or of the chassis, element, or faceplate of the chassis. In alternative embodiments, the apparatus may be assembled onto the electronics or the chassis, element, or faceplate of the chassis. Assembling may include positioning, welding, gluing, fastening, taping, or other assembly technique known in the art.

Methods for dissipating heat from electronics may comprise enabling an airflow to flow along an airflow passageway defined by a drafted air duct, spanning between an intake port end and an exhaust port end with an aperture of greater cross-sectional area than an aperture of the intake port end, of sufficient volume to contain at least a portion of electronics and retaining sufficient spatial proximity to a chassis of a system with internal convection cooling such that the airflow within the chassis can influence the airflow in the airflow passageway. Further methods can include causing the active convection cooling to commence within the chassis, such as by activating at least one fan within the chassis, wherein the activating may be done locally or remotely by an engineer, technician, other personnel, or automated supervisory system, for example. Further methods may also include enable additional airflow to enter the airflow passageway through apertures (perforations) located adjacent to an intake port end.

An apparatus for dissipating heat from electronics may have means for enabling an airflow to flow through an airflow passageway, spanning between an intake port end and an exhaust port end with an aperture of greater cross-sectional area than an aperture of the intake port end, with sufficient volume to contain at least a portion of the electronics and means for fluidically coupling the airflow within a chassis of a system with internal convection cooling to influence at least in part the airflow in the airflow passageway.

The teachings of all patents, published applications and references cited herein are incorporated by reference in their entirety

While example embodiments have been particularly shown and described, it will be understood by those skilled in the art that various changes in form and details may be made therein without departing from the scope of the embodiments encompassed by the appended claims.

What is claimed is:

1. An apparatus for dissipating heat from electronics, comprising:
an intake port end defining at least a portion of a boundary of an intake aperture;
an exhaust port end defining at least a portion of a boundary of an exhaust aperture with a cross-sectional area greater than a cross-sectional area of the intake port aperture, the exhaust port end configured to couple fluidically with an element of a chassis of a system with internal convection cooling, the element being permeable to an airflow between an external environment and an internal volume of the chassis; and
a drafted air duct spanning between the intake port end and the exhaust port end and defining at least a portion of an airflow passageway, from the intake port end to the exhaust port end, with sufficient volume to contain therein at least a portion of the electronics, the airflow passageway arranged to dissipate heat from the electronics along a direction of the airflow created by the convection cooling.

2. The apparatus of claim 1, wherein the exhaust port end is configured to couple fluidically with the element of the chassis, the element being a flat faceplate or faceplate that is at least in part angled with respect to another part of the faceplate or member of the chassis.

3. The apparatus of claim 1, wherein the drafted air duct defines at least a portion of an airflow passageway with volume sufficient to contain at least a portion of an individual or a plurality of electronic components and any heatsinks thermally coupled thereto.

4. The apparatus of claim 1, wherein a plurality of drafted air ducts defines at least a portion of an airflow passageway around a plurality of electronic components, each drafted air duct defining at least a portion of an airflow passageway around an individual or a plurality of electronic components, the plurality of drafted air ducts being interconnected with respect to one another or having at least two adjacent air ducts coupled to each other.

5. The apparatus of claim 1, wherein the drafted air duct defines an arrangement of perforations at a location adjacent to the intake port end.

6. The apparatus of claim 1, wherein the exhaust port end defines an exhaust aperture of the same shape and of greater respective dimensions than the intake aperture defined by an intake port end.

7. The apparatus of claim 1, wherein the drafted air duct is formed of a single continuous material molded to form the drafted air duct.

8. The apparatus of claim 1, wherein the drafted air duct is formed of a plurality of flat or curved panels coupled together.

9. The apparatus of claim 8, wherein at least one of the plurality of the panels is tapered.

10. The apparatus of claim 1, wherein the drafted air duct is configured to be assembled onto the electronics.

11. The apparatus of claim 1, wherein the drafted air duct is configured to be assembled onto the chassis of the system with the internal convection cooling, including onto the element permeable to the airflow.

12. The apparatus of claim 1, wherein the drafted air duct is an integrated component of the electronics.

13. The apparatus of claim 1, wherein the drafted air duct is an integrated component of the chassis or element of the chassis.

14. The apparatus of claim 1, further comprising a heatsink with fins thermally coupled to the electronics, and wherein the fins of the heatsink form at least a portion of the drafted air duct.

15. The apparatus of claim 1, wherein the electronics at least in part within the airflow passageway include a quad small form-factor pluggable optical transceiver module.

16. The apparatus of claim 15, wherein the optical transceiver module includes an integrated heatsink, and wherein the drafted air duct is configured to at least partially contain the optical transceiver module.

17. A method for dissipating heat from electronics, comprising:
enabling an airflow to flow along an airflow passageway spanning from an intake port end to an exhaust port end, the airflow passageway defined in part by a cross-sectional area at the exhaust port end that is greater than the cross-sectional area of the intake port end and encompassing sufficient volume to contain therein at least a portion of the electronics; and
retaining spatial proximity to a chassis of a system with internal convectional cooling, the spatial proximity enabling fluidic coupling of airflow in the chassis with the airflow in the airflow passageway.

18. The method of claim 17, further comprising causing the convectional cooling to commence within the chassis.

19. The method of claim 17, further comprising enabling additional airflow to enter the airflow passageway through apertures located adjacent to the intake port end.

20. An apparatus for dissipating heat from electronics, comprising:
means for enabling an airflow to flow along an airflow passageway spanning from an intake port end to an exhaust port end, the airflow passageway including a cross-sectional area at the exhaust port end that is greater than the cross-sectional area of the intake port end and encompassing sufficient volume to contain therein at least a portion of the electronics; and
means for fluidically coupling an airflow within a chassis of a system with internal convection cooling to influence at least in part the airflow in the airflow passageway.
